(19) United States
(12) Patent Application Publication
(10) Pub. No.: US 2006/0086997 A1
(43) Pub. Date: Apr. 27, 2006

(54) Schottky barrier diode

(75) Inventors: Koh Kanaya, Tokyo (JP); Yasuki Aihara, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/235,239

(22) Filed: Sep. 27, 2005

(30) Foreign Application Priority Data
Oct. 22, 2004 (JP) 2004-307890

(51) Int. Cl. H01L 31/07

(52) U.S. Cl. 257/471

(57) ABSTRACT

A buffer layer made of i-GaAs not doped with impurities, and an n⁺ GaAs layer doped with a high-concentration of n-type impurities are stacked in the order named on a semi-insulating GaAs substrate. An n⁻ GaAs layer doped with a low-concentration of n-type impurities is partially located on the n⁺ GaAs layer. Cathode electrodes are located in opening regions in which the n⁻ GaAs layer is not present on the n⁺ GaAs layer. An anode electrode is located on the n⁻ GaAs layer. The n⁺ GaAs layer has a carrier concentration of 5×10¹⁸ cm⁻³, and is in ohmic contact with the cathode electrodes. The n⁻ GaAs layer has a carrier concentration of 1.2×10¹⁷ cm⁻³, and is in Schottky contact with the anode electrode.

### BACKGROUND OF THE INVENTION

1. Field of the Invention

The present invention relates to a Schottky barrier diode and, more particularly, to a technique for reducing noise in a mixer for use in electronic and communication equipment in microwave and millimeter-wave bands.

2. Description of the Background Art

A MMIC (monolithic microwave IC) in which a plurality of devices including microwave and millimeter-wave mixers are mounted on a single substrate is required not only to increase the performance thereof but also to reduce the size and cost thereof. In recent years, a homodyne scheme which converts an input signal into an IF (intermediate frequency) signal having a frequency as low as 100 kHz has been often employed in a millimeter-wave system. It is essential for a receiver mixer for use in the homodyne scheme to reduce the noise figure NF thereof. The noise figure NF of the mixer which converts the input signal into the IF signal having such a low frequency is significantly influenced by 1/f noise in a device used in the mixer. The 1/f noise refers to noise whose level is in inverse proportion to the frequency, and is dominant in a frequency band as low as 100 kHz.

In the light of the size reduction and cost reduction, it is an effective method to form a low noise amplifier (referred to hereinafter as an LNA) and the mixer on the same chip by using a HEMT (high electron mobility transistor) process. A typical configuration is such that a HEMT is used for the LNA, and a HEMT or a Schottky barrier diode (referred to hereinafter as an SBD) constructed by connecting the source and the drain of the HEMT to each other is used for the mixer. It is, however, difficult for the HEMT to provide a sufficient low noise characteristic in a low intermediate frequency band because the HEMT generally has extremely high 1/f noise.

A Si-SBD mixer using a Si-SBD is effective in the light of the increase in performance and the decrease in noise for the receiver mixer. Because the Si-SBD is lower in 1/f noise than a GaAs-SBD, the Si-SBD mixer can provide a good noise characteristic. It is, however, inappropriate to mount all of the devices on a Si substrate because the transmission line loss of the Si substrate is extremely high in the microwave and millimeter-wave bands. Thus, a need arises to construct the millimeter-wave system by using a MIC (microwave IC) employing a plurality of substrates, rather than the MMIC. Consequently, the Si-SBD mixer is not suitable for the size reduction and the cost reduction.

Examples of conventional diodes, and MMICs and mixers employing the conventional diodes are disclosed, for example, in Japanese Patent Application Laid-Open No. 2001-177060 (FIG. 3), Japanese Patent Application Laid-Open No. 2002-299570, Japanese Patent Application Laid-Open No. 10-51012 (1998) (FIGS. 10 and 11), Japanese Patent Application Laid-Open No. 2003-69048 (FIG. 1), and Japanese Patent No. 2795972 (FIG. 1).

As mentioned above, the size reduction and cost reduction of the receiver mixer require the formation of the plurality of devices in the form of the MMIC on the same chip by using the GaAs-SBD, rather than the Si-SBD. Also, the increase in the performance of the receiver mixer requires the reduction in 1/f noise which is dominant at the intermediate frequency in the GaAs-SBD.

Japanese Patent Application Laid-Open No. 2001-177060 and Japanese Patent Application Laid-Open No. 2002-299570 disclose that an etching stopper layer made of AlGaAs and the like is disposed between an n⁺ GaAs layer and an n⁻ GaAs layer over a GaAs substrate. The provision of such an etching stopper layer creates a problem such that a deep level in AlGaAs near a Schottky interface induces the 1/f noise. There arises another problem such that the increase in series resistance component in the SBD decreases the conversion gain of the frequency conversion in the mixer using the SBD to increase the noise figure.

Japanese Patent Application Laid-Open No. 10-51012 discloses the effect of reducing a resistance by etching down into an n⁻ GaAs layer, but does not disclose the effect of reducing noise.

Japanese Patent Application Laid-Open No. 2003-69048 discloses that a high-concentration ion-implanted region is formed between an n GaAs layer and an electrode for the purpose of providing an ohmic contact therebetween. This, however, presents a problem such that crystal defects are created in a GaAs substrate to induce noise when ion implantation is performed. Another problem is such that the high-concentration ion-implanted region, which is higher in resistance than metal, results in the increase in noise figure.

### SUMMARY OF THE INVENTION

It is an object of the present invention to provide a Schottky barrier diode capable of reducing noise while achieving size reduction and cost reduction.

According to an aspect of the present invention, a Schottky barrier diode includes an epitaxial structure, a cathode electrode, and an anode electrode. The epitaxial structure includes a buffer layer, a high carrier concentration GaAs layer, and a low carrier concentration GaAs layer stacked in the order named and formed by an epitaxial process on a semi-insulating GaAs substrate. The cathode electrode is formed in ohmic contact with the high carrier concentration GaAs layer. The anode electrode is formed in Schottky contact with the low carrier concentration GaAs layer. An active region containing the low carrier concentration GaAs layer is formed so as to surround the cathode electrode and the anode electrode in a layout pattern as seen in plan view.

This reduces a series resistance component and a capacitance component, thereby to improve a conversion gain and reduce a noise figure with low LO power when a frequency conversion is performed in a mixer. In other words, the higher performance of the mixer is attained.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of principal parts of an SBD according to a first preferred embodiment of the present invention;

FIG. 2 is a graph showing changes in output noise power as a function of current;

FIG. 3 is a graph showing changes in output noise power as a function of carrier concentration;

FIGS. 4 to 7 are top plan views of the SBD;

FIG. 8 is a graph showing changes in output noise power as a function of current;

FIGS. 9A to 9C are sectional views showing a method of manufacturing the SBD;

FIG. 10 is a top plan view of an APDP with a pair of SBDs connected in anti-parallel to each other;

FIG. 11 is a diagram of a mixer; and

FIG. 12 is a graph showing changes in noise figure as a function of LO power.

### DESCRIPTION OF THE PREFERRED EMBODIMENTS

### First Preferred Embodiment

A receiver mixer according to a first preferred embodiment of the present invention is characterized by the use of a GaAs-SBD (Schottky barrier diode) for purposes of size reduction and cost reduction and by the reduction in noise at an intermediate frequency in the GaAs-SBD.

In general, the noise figure NF of a mixer is expressed as:

$$NF = \frac{Si / Ni}{So / No} = \frac{No}{GcNi} \qquad ( 1 )$$

where Si is input signal power, Ni is input noise power, So is output signal power, No is output noise power, and Gc is a conversion gain.

The input noise power Ni is a constant determined by temperature. Thus, Equation (1) shows that the noise figure NF depends on the output noise power No generated in the SBD and the conversion gain Gc.

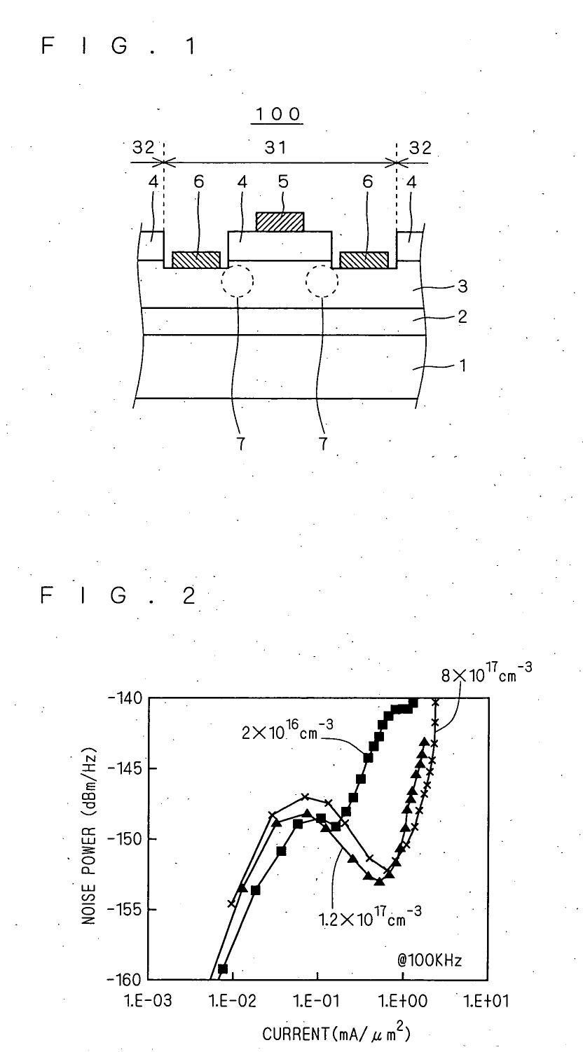

FIG. 1 is a sectional view showing a structure of principal parts of an SBD 100 according to the first preferred embodiment of the present invention. Parts which are not directly relevant to the present invention are not shown in FIG. 1.

With reference to FIG. 1, for example, a buffer layer 2 made of i-GaAs not implanted with impurities, and an n⁺ GaAs layer 3 (high carrier concentration GaAs layer) implanted with high-concentration n-type impurities are formed in the order named on a semi-insulating GaAs substrate 1. An n⁻ GaAs layer 4 (low carrier concentration GaAs layer) implanted with low-concentration n-type impurities is formed partially on the n⁺ GaAs layer 3. Cathode electrodes 6 are formed in opening regions in which the n⁻ GaAs layer 4 is not formed on the n⁺ GaAs layer 3. An anode electrode 5 is formed on the n⁻ GaAs layer 4.

The buffer layer 2, the n⁺ GaAs layer 3, and the n⁻ GaAs layer 4 are formed by an epitaxial process on the GaAs substrate 1. In other words, the GaAs substrate 1, the buffer layer 2, the n⁺ GaAs layer 3 and the n⁻ GaAs layer 4 function as an epitaxial structure according to the present invention. The SBD 100 is constructed such that an insulation region 32 for isolation between devices is formed outside an active region 31 in which the n⁻ GaAs layer 4 is included and in which a diode body is formed.

The n⁺ GaAs layer 3 has a high carrier concentration of 5×10¹⁸ cm⁻³, and is in ohmic contact with the cathode electrodes 6. The n⁺ GaAs layer 3 has a thickness of 6000 Å.

The n⁻ GaAs layer 4 has a low carrier concentration of 1.2×10¹⁷ cm⁻³, and is in Schottky contact with the anode electrode 5. The n⁻ GaAs layer 4 has a thickness of 4000 Å.

In the SBD 100, the buffer layer 2 is disposed between the GaAs substrate 1 and a semiconductor layer including the n⁺ GaAs layer 3 and the n GaAs layer 4 and serving as a current path. Because 1/f noise is considered to result from crystal defects, such a construction reduces the influence of the defects in the GaAs substrate 1.

Currents are locally concentrated in regions 7 which are contained in the n⁺ GaAs layer 3 and lie under the opposite ends of the anode electrode 5. In the regions 7, because electric fields are concentrated therein, the 1/f noise tends to increase accordingly. The 1/f noise is considered to be in inverse proportion to the number of carriers. The SBD 100 can increase the carrier concentration in the regions 7 to reduce the 1/f noise by setting the carrier concentration in the n⁺ GaAs layer 3 at a relatively high value of 5×10¹⁸ cm⁻³.

Referring to FIG. 1, etching is performed so that the n⁺ GaAs layer 3 is overetched when the openings are formed in the n GaAs layer 4. Such etching enables the thickness of the n⁻ GaAs layer 4 after the etching to be throughout equal to the thickness of the n⁻ GaAs layer 4 formed by the epitaxial process before the etching (that is, no n⁻ GaAs layer 4 left in the opening regions after the etching). This reduces variations in the thickness of the n⁻ GaAs layer 4 serving as a Schottky layer due to the etching, thereby to reduce variations in 1/f noise resulting from variations in the number of carriers based on the variations in thickness of the n⁻ GaAs layer 4. The first preferred embodiment according to the present invention further reduces the variations in 1/f noise, as compared with Japanese Patent Application Laid-Open No. 10-51012 which discloses the process of etching down into the n⁻ GaAs layer. Additionally, the first preferred embodiment, which does not perform the process of etching down, can hold the thickness of the n⁻ GaAs layer 4 accordingly larger to keep a greater number of carriers contained in the n⁻ GaAs layer 4, thereby achieving further reduction in 1/f noise, as compared with Japanese Patent Application Laid-Open No. 10-51012. The execution of the overetching causes variations in the thickness of the n⁺ GaAs layer 3. However, the influence of the variations in the thickness of the n⁺ GaAs layer 3 serving as an ohmic layer upon the 1/f noise is extremely slight and does not become a problem.

Further, the carrier concentration and volume of the n⁻ GaAs layer 4 are preferably higher because the 1/f noise is considered to be in inverse proportion to the number of carriers, as mentioned above.

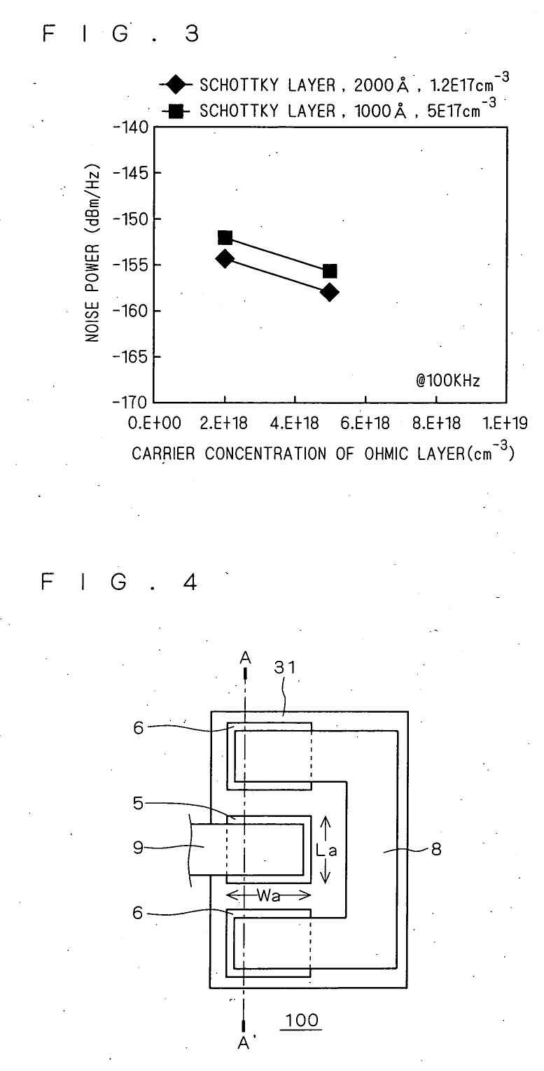

FIG. 2 is a graph showing changes in output noise power No as a function of current when the carrier concentrations of the n⁻ GaAs layer 4 are 2×10¹⁶ cm⁻³, 1.2×10¹⁷ cm⁻³, and 8×10¹⁷ cm⁻³. A plot of the output noise power No at an intermediate frequency of 100 kHz is also shown in FIG. 2 (and also in FIGS. 3 and 8) by using current per unit area.

Because the receiver mixer is excited by LO (local oscillation) power, it is desirable that the output noise power No is low at least in a region where the current is not greater than 1 mA/μm², As shown in FIG. 2, when the carrier concentration is as low as 2×10¹⁶ cm⁻³, the output noise power No is high in the region where the current is not greater than 1 mA/μm². On the other hand, when the carrier concentrations are 1.2×10¹⁷ cm⁻³ and 8×10¹⁷ cm⁻³, the output noise power No is low in the region where the current is not greater than 1 mA/μm². The results of experiments have revealed that the output noise power No in the region where the current is not greater than 1 mA/μM² can be relatively low when the carrier concentration of the n⁻ GaAs layer 4 is not less than 1×10¹⁷ cm⁻³. However, too high a carrier concentration in the n⁻ GaAs layer 4 serving as the Schottky layer is considered to create the problem of the decrease in reverse breakdown voltage. The results of experiments have revealed that the reverse breakdown voltage can be increased to such a degree that the practical use of a mixer constructed using the SBD 100 is permitted when the carrier concentration of the n⁻ GaAs layer 4 is not greater than 8×10¹⁷ cm⁻³. That is, setting the carrier concentration of the n⁻ GaAs layer 4 in the range from 1×10¹⁷ to 8×10¹⁷ cm⁻³ allows the reduction in output noise power No while ensuring the breakdown voltage.

FIG. 3 is a graph showing changes in output noise power No as a function of the carrier concentration of the n⁺ GaAs layer 3 serving as the ohmic layer when combinations of the thicknesses and carrier concentrations of the n⁻ GaAs layer 4 serving as the Schottky layer are (2000 Å, and 1.2×10¹⁷ cm⁻³) and (1000 Å, and 5×10¹⁷ cm⁻³). Referring to FIG. 3, the higher the carrier concentration of the n⁺ GaAs layer 3 is, the lower the output noise power No is. The results of experiments have revealed that the output noise power No can be lowered to such a degree that the practical use of the mixer constructed using the SBD 100 is permitted when the carrier concentration of the n⁺ GaAs layer 3 is not less than 1×10¹⁸ cm⁻³.

The thicknesses of the n⁺ GaAs layer 3 and the n⁻ GaAs layer 4 are preferably greater because the 1/f noise is considered to be in inverse proportion to the number of carriers, as mentioned above. Further, as the thickness of the n⁺ GaAs layer 3 serving as the ohmic layer is increased, the resistance component and the influence of the defects in the GaAs substrate 1 are decreased, and the output noise power No is accordingly decreased. The results of experiments have revealed that the output noise power No can be lowered to such a degree that the practical use of the mixer constructed using the SBD 100 is permitted when the thickness of the n⁺ GaAs layer 3 is not less than 1000 Å. Additionally, the results of experiments have revealed that the output noise power No can be lowered to such a degree that the practical use of the mixer constructed using the SBD 100 is permitted when the thickness of the n⁻ GaAs layer 4 is not less than 1000 Å.

FIG. 4 is a top plan view of the SBD 100. A section taken along the line A-A′ of FIG. 4 corresponds to that of FIG. 1.

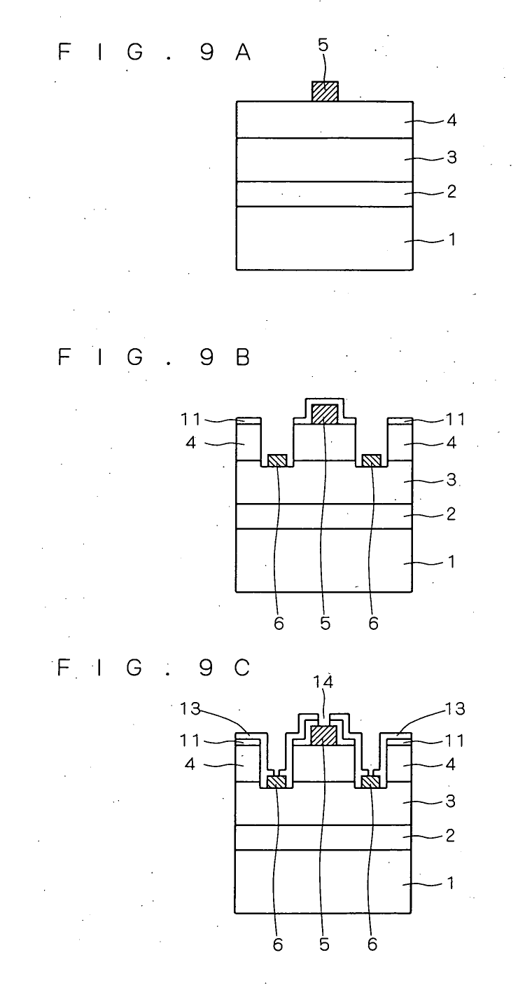

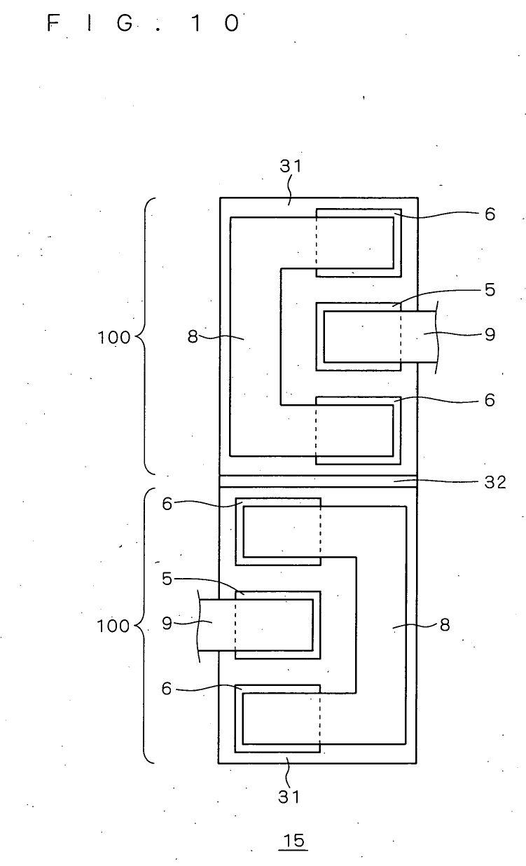

FIG. 4 shows a layout pattern of the SBD 100 as seen in plan view. The two cathode electrodes 6 are connected to each other through a transmission line 8. An anode extension interconnect line 9 is connected to the anode electrode 5. The transmission line 8 and the anode extension interconnect line 9 are insulated from the n⁺ GaAs layer 3 and the n GaAs layer 4, respectively, by a SiN film (not shown in FIG. 4 and the like), as will be described later with reference to FIGS. 9A to 9C.

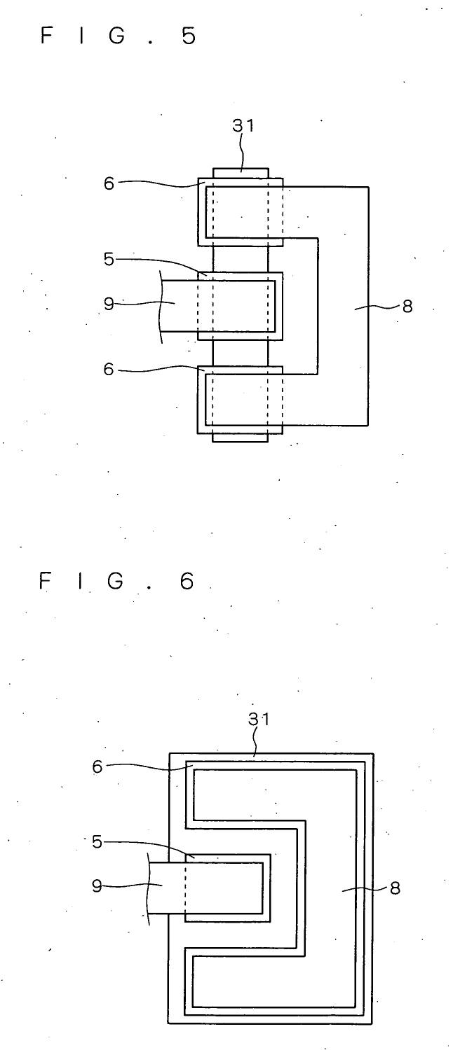

For the layout pattern shown in FIG. 4, the active region 31 is formed to extend over a wide area so as to surround the anode electrode 5 and the cathode electrodes 6. Because the current flows from the anode electrode 5 toward the cathode electrodes 6 in the active region 31, the area of a cross section of the active region 31 perpendicular to a direction in which the current flows becomes small when the active region 31 is formed to extend over a relatively narrow area, for example, as shown in FIG. 5. This creates the problem of an increased series resistance component against the current. As illustrated in FIG. 4, making a dimension of the active region 31 as measured in a first direction perpendicular to a second direction in which the anode electrode 5 and the cathode electrodes 6 are arranged greater than dimensions of the anode electrode 5 and cathode electrodes 6 as measured in the first direction provides the active region 31 so as to surround the anode electrode 5 and cathode electrodes 6, thereby reducing the resistance component. Additionally, the anode electrode 5 and the cathode electrodes 6 may be reduced in size by the amount of the increased Schottky contact areas with the active region 31, thereby decreasing a capacitance component.

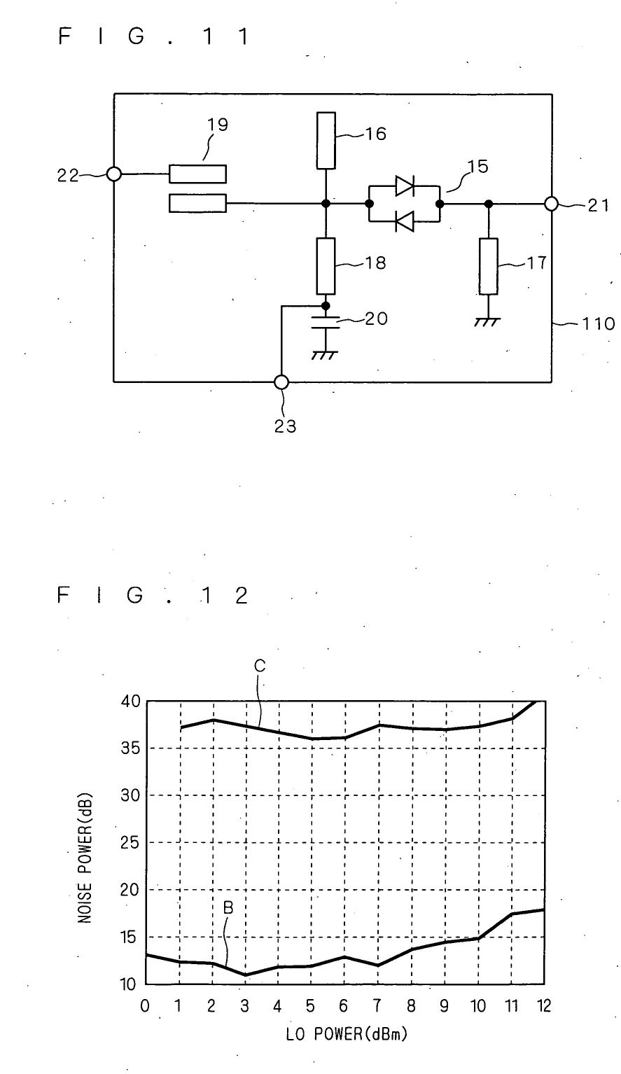

The SBD 100 makes a frequency conversion in the mixer, which will be described later with reference to FIGS. 10 and 11. The increased capacitance component hinders the LO power from being efficiently inputted to the resistance component of the SBD 100. Thus, when the LO power is increased, the output noise power No increases, but the conversion gain Gc in Equation (1) decreases and the noise figure NF accordingly increases. Therefore, forming the active region 31 extending over a wide area to decrease the capacitance component improves the conversion gain Gc to reduce the noise figure NF with low LO power. That is, the higher performance of the mixer is attained.

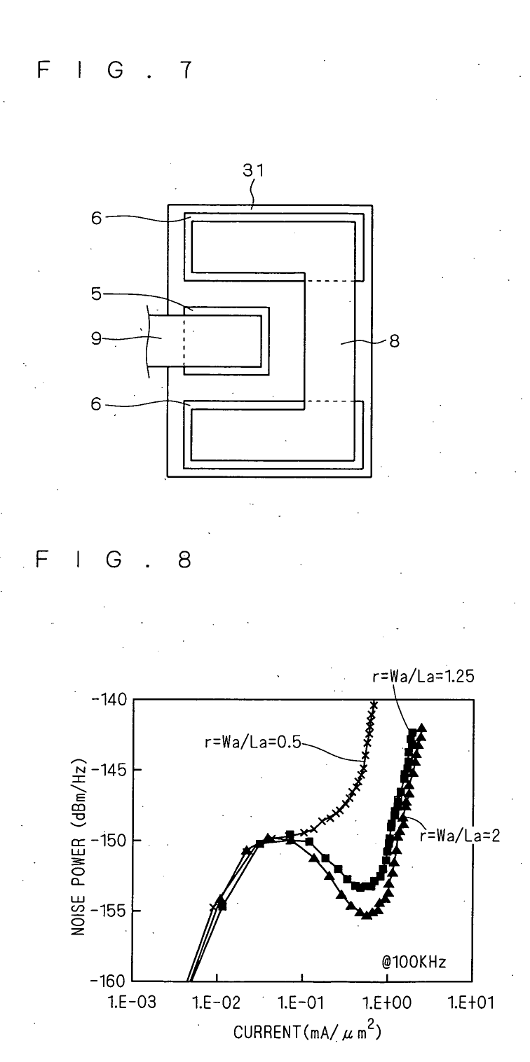

With reference to FIG. 4, the two cathode electrodes 6 (first and second cathode electrodes) and the single anode electrode 5 are equal in length to each other and are arranged in parallel with each other. For example, as shown in FIG. 6, the formation of a single cathode electrode 6 of a generally U-shaped configuration, rather than the two cathode electrodes 6, results in the increased area of the cathode electrode 6 to present the problem of a higher capacitance component as compared with that of FIG. 4. The arrangement of the two cathode electrodes 6 and the single anode electrode 5 in parallel to each other as shown in FIG. 4 provides the lower capacitance component. This improves the conversion gain Gc to reduce the noise figure NF with the low LO power. The provision of the two cathode electrodes 6 longer than the anode electrode 5, for example, as shown in FIG. 7 results in the higher capacitance component as compared with that of FIG. 4 but is advantageous in reduction in resistance component.

With reference to FIG. 4, an anode width Wa which is the dimension of the anode electrode 5 as measured in the first direction is 5 μm, and an anode length La which is a dimension of the anode electrode 5 as measured in the second direction is 4 μm. The ratio r of the anode width Wa to the anode length La is expressed as r= 5/4=1.25.

In the SBD 100 shown in FIG. 4, the greater the anode width Wa is, the greater the volume of the n⁻ GaAs layer 4 in contact with the anode electrode 5 is and the lower the output noise power No in Equation (1) is. However, the increase in anode width Wa increases the capacitance component to decrease the conversion gain Gc, thereby increasing the noise figure NF. The results of experiments have revealed that the conversion gain Gc is improved and the noise figure NF is reduced with the low LO power when the anode width Wa is 4 to 10 μm.

FIG. 8 is a graph showing changes in output noise power No as a function of the current when the ratio r=Wa/La equals 0.5, 1.25 and 2. As shown in FIG. 8, when the ratio r=0.5, the output noise power No is high in the region where the current is not greater than 1 mA/μm². On the other hand, when the ratio r=1.25 and when the ratio r=2, the output noise power No is relatively low in the region where the current is not greater than 1 mA/μm². When the ratio r>3, the LO power is not efficiently inputted to the resistance component of the SBD 100. This decreases the conversion gain Gc to increase the noise figure NF in Equation. (1). The results of experiments have revealed that, when the ratio r ranges from 1 to 3, the output noise power No in the region where the current is not greater than 1 mA/μm² is relatively low, the conversion gain Gc is improved, and the noise figure NF is reduced with the low LO power.

FIGS. 9A to 9C are sectional views showing a method of manufacturing the SBD 100.

First, as shown in FIG. 9A, the buffer layer 2 made of i-GaAs, the n⁺ GaAs layer 3 and the n GaAs layer 4 are formed on the semi-insulating GaAs substrate 1 by an epitaxial process. Next, impurity ions of hydrogen and the like are implanted, with a diode formation region covered with a resist mask, for the purpose of electrically insulating a diode from other regions on the wafer, thereby to form the insulation region 32 (not shown in FIGS. 9A to 9C). Next, an evaporation and lift-off process is used to form the anode electrode 5 on the n⁻ GaAs layer 4. The formation of the anode electrode 5 is carried out by the vapor deposition of metal on the n⁻ GaAs layer 4 and the processing of the deposited metal, using a resist mask having an opening in a region where the anode electrode 5 is to be formed.

Next, as shown in FIG. 9B, a SiN film 11 is formed on the n⁻ GaAs layer 4 and the anode electrode 5 by a CVD process. Next, the SiN film 11 is anisotropically etched by a RIE (reactive ion etching) process using a resist mask having openings in regions where the cathode electrodes 6 are to be formed, whereby the n⁻ GaAs layer 4 is exposed. Next, isotropic etching using a mixture of tartaric acid and hydrogen peroxide solution is performed on the exposed n⁻ GaAs layer 4 in a time-controlled manner to expose the n⁺ GaAs layer 3. Next, an evaporation and lift-off process using metal such as AuGe and the like is performed to form the cathode electrodes 6 on the exposed n⁺ GaAs layer 3. Next, heat treatment is carried out at 360° C. for about two minutes. Next, a SiN film 13 is formed by a CVD process entirely over the n⁺ GaAs layer 3, the cathode electrodes 6 and the SiN film 11.

Next, as shown in FIG. 9C, the SiN film 13 is etched by a RIE process using a resist mask having openings over the anode electrode 5 and cathode electrodes 6, whereby contact holes 14 are formed. Next, the anode extension interconnect line 9 and the transmission line 8 (both not shown in FIGS. 9A to 9C) are formed in such a manner as to extend out of the contact holes 14. The SBD 100 is manufactured by the above-mentioned procedure. The SiN film 11, the SiN film 13 and the like shown in FIGS. 9A to 9C are not shown in FIGS. 1 to 4 for purposes of description.

FIG. 10 is a top plan view showing a construction of an anti-parallel diode pair (referred to hereinafter as an APDP) 15 including a pair of SBDs 100 each shown in FIG. 4 and connected in anti-parallel with each other, with an insulating region (isolation region) disposed therebetween. FIG. 11 is a diagram of a mixer 110 which employs the APDP 15 of FIG. 10 as an APDP in a circuit configuration substantially similar to the mixer disclosed in Japanese Patent No. 2795972 (FIG. 1).

As illustrated in FIG. 11, the mixer 110 includes the APDP 15, an open stub 16, shorted stubs 17 and 18, a filter 19, a capacitance 20, an LO input terminal 21, an RF (radio frequency) input terminal 22, and an IF output terminal 23.

With reference to FIG. 11, the mixer 110 mixes an LO signal inputted at the LO input terminal 21 and an RF signal inputted at the RF input terminal 22 to output an IF signal at the IF output terminal 23.

The open stub 16 is open at its one end, and has a length corresponding to one-quarter wavelength of the LO signal. The shorted stub 17 is shorted at its one end, and has a length corresponding to one-quarter wavelength of the LO signal. The shorted stub 18 is shorted at its one end, and has a length corresponding to one-quarter wavelength of the RF signal. The filter 19 allows the RF signal to pass therethrough.

Because the SBD 100 turns on during the positive half cycle of the LO signal and during the negative half cycle thereof, the IF signal (the frequency of which is designated by f_{IF}) is outputted as a mixture of the second harmonic of the LO signal (the frequency of which is designated by f_{LO}), and the RF signal (the frequency of which is designated by f_{RF}), as expressed by
f_{IF}=|f_{RF}−2f_{LO}| (2)

Because the intermediate frequency is sufficiently lower than the radio frequency and the LO frequency in the homodyne scheme, the relation between the LO frequency and the radio frequency is expressed as:
f_{RF}≅2f_{LO} (3)

That is, the LO frequency is required only to be one-half the radio frequency. Thus, the mixer 110 constructed as shown in FIG. 11 is appropriate especially for a millimeter-wave system.

The open stub 16, the shorted stubs 17 and 18, and the filter 19 have the function of separating the LO signal, the RF signal and the IF signal.

Because the open stub 16 and the shorted stub 17 have the length corresponding to one-quarter wavelength of the LO signal, the APDP 15 is shorted on the RF input terminal 22 side and is open on the LO input terminal 21 side at the LO frequency. Therefore, the separation may be performed so that the LO signal inputted at the LO input terminal 21 is inputted only to the APDP 15.

From Equation (3), the open stub 16 and the shorted stub 17 have the length corresponding to one-half wavelength of the RF signal. Thus, the APDP 15 is open on the RF input terminal 22 side and is shorted on the LO input terminal 21 side at the radio frequency. Therefore, the separation may be performed so that the RF signal inputted at the RF input terminal 22 is inputted only to the APDP 15.

Because the shorted stub 18 has the length corresponding to one-quarter wavelength of the RF signal, the APDP 15 is open on the IF output terminal 23 side and the RF signal is not outputted to the IF output terminal 23 at the radio frequency. The IF signal is outputted only to the IF output terminal 23 because the open stub 16, the filter 19, and the capacitance 20 are open.

FIG. 12 shows measurement values B of the noise figure NF for the mixer 110 shown in FIG. 11 constructed using a MMIC. In FIG. 12, the abscissa represents the LO power, and the ordinate represents the noise figure NF. Measurement values C of the noise figure NF for a mixer similar in circuit configuration to that of FIG. 11 using the SBD constructed by connecting the source and the drain of the conventional HEMT to each other are also shown in FIG. 12 for purposes of comparison.

As indicated as the measurement values B in FIG. 12, the noise figure NF is not greater than 15 dB when the LO power is not greater than 10 dBm in the mixer 110 using the SBD 100. Comparing the measurement values B with the measurement values C shows that the noise figure NF is reduced by 20 dB or more.

As described hereinabove, the SBD 100 according to this preferred embodiment is capable of reducing the output noise power No while ensuring the breakdown voltage by setting the carrier concentration of the n⁻ GaAs layer 4 at 1×10¹⁷ to 8×10¹⁷ cm⁻³. This allows the reduction in noise while achieving the size reduction and the cost reduction.

In the SBD 100, the active region 31 is formed to extend over a wide area in such a manner as to surround the anode electrode 5 and the cathode electrodes 6. This decreases the series resistance component and the capacitance component, thereby to improve the conversion gain Gc and reduce the noise figure NF with the low LO power when a frequency conversion is performed in the mixer 110. In other words, the higher performance of the mixer is attained.

While the invention has been described in detail, the foregoing description is in all aspects illustrative and not restrictive. It is understood that numerous other modifications and variations can be devised without departing from the scope of the invention.

1. A Schottky barrier diode comprising:
an epitaxial structure including a buffer layer, a high carrier concentration GaAs layer, and a low carrier concentration GaAs layer, stacked in the order named on a semi-insulating GaAs substrate;
a cathode electrode in ohmic contact with said high carrier concentration GaAs layer; and
an anode electrode in Schottky contact with said low carrier concentration GaAs layer, wherein an active region containing said low carrier concentration GaAs layer surrounds said cathode electrode and said anode electrode in a layout pattern as seen in plan view.

2. The Schottky barrier diode according to claim 1, wherein said low carrier concentration GaAs layer has a carrier concentration in a range from 1×10¹⁷ to 8×10¹⁷ cm⁻³.

3. The Schottky barrier diode according to claim 1, wherein said low carrier concentration GaAs layer has a thickness of not less than 1000 Å.

4. The Schottky barrier diode according to claim 1, wherein said high carrier concentration GaAs layer has a carrier concentration of not less than 1×10¹⁸ cm⁻³.

5. The Schottky barrier diode according to claim 1, wherein said high carrier concentration GaAs layer has a thickness of not less than 1000 Å.

6. The Schottky barrier diode according to claim 1, wherein
said cathode electrode includes a first cathode electrode and a second cathode electrode, and
said first cathode electrode, said second cathode electrode, and said anode electrode are parallel to each other.

7. The Schottky barrier diode according to claim 6, wherein anode width divided by anode length ranges from 1 to 3, the anode width being a dimension of said anode electrode as measured in a first direction, perpendicular to a second direction along which said first and second cathode electrodes and said anode electrode are arranged, the anode length being a dimension of said anode electrode as measured in the second direction.

8. The Schottky barrier diode according to claim 6, wherein anode width is 4 to 10 μm, the anode width being a dimension of said anode electrode as measured in a direction perpendicular to a direction along which said first and second cathode electrodes and said anode electrode are arranged.

9. The Schottky barrier diode according to claim 7, wherein said anode width is 4 to 10 μm.
